(19) United States
(12) Patent Application Publication
(10) Pub. No.: US 2012/0086487 A1
(43) Pub. Date: Apr. 12, 2012

(54) SEMICONDUCTOR DEVICE

(75) Inventor: Keisuke KISHISHITA, Kyoto (JP)

(73) Assignee: Panasonic Corporation, Osaka (JP)

(21) Appl. No.: 13/329,875

(22) Filed: Dec. 19, 2011

Related U.S. Application Data
(63) Continuation of application No. PCT/JP2010/002039, filed on Mar. 23, 2010.

(30) Foreign Application Priority Data
Jul. 27, 2009 (JP) 2009-173998

(51) Int. Cl. H03L 7/08; H03L 7/00

(52) U.S. Cl. 327/158; 327/161

(57) ABSTRACT

A semiconductor device includes a monitoring circuit including a delay circuit including a plurality of elements and a plurality of interconnects arranged in a tree shape, a data supply circuit configured to supply a determination signal to the delay circuit, and a delay evaluation circuit connected to an end point of the delay circuit and configured to evaluate a delay state of the determination signal. The monitoring circuit controls at least one of a power supply voltage, a substrate voltage, and a clock frequency of a semiconductor circuit included in the semiconductor device based on an output of the delay evaluation circuit. The circuits included in the monitoring circuit are arranged in a space in the semiconductor device using a layout tool, whereby highly accurate delay monitoring can be performed while reducing an increase in area.

### CROSS-REFERENCE TO RELATED APPLICATIONS

This is a continuation of PCT International Application PCT/JP2010/002039 filed on Mar. 23, 2010, which claims priority to Japanese Patent Application No. 2009-173998 filed on Jul. 27, 2009. The disclosures of these applications including the specifications, the drawings, and the claims are hereby incorporated by reference in their entirety.

### BACKGROUND

The present disclosure relates to delay monitoring circuits for semiconductor devices, and more particularly, to a circuit configuration of the monitoring circuit and a physical arrangement of the monitoring circuit in the semiconductor device.

In recent years, power consumption has increased significantly in a semiconductor device having many functions. However, there is a demand for a reduction in the power consumption of a semiconductor device in order to efficiently use earth resources. To reduce the power consumption, there is a widely known technique which is called “dynamic voltage and frequency scaling (DVFS),” in which the circuit operating state of a semiconductor device is monitored and the device is operated at as low a voltage and frequency as possible.

Conventionally, there is a known technique of reducing power consumption by monitoring a delay value of a replica circuit mimicking a critical path which it takes the longest time to pass through when a semiconductor device operates at a predetermined frequency and, based on the delay value, controlling a value of a power supply voltage supplied to the semiconductor circuit. With this technique, the power supply voltage can be reduced to the extent possible within a range in which the semiconductor circuit does not operate erroneously, whereby power consumption can be reduced (see Japanese Patent Publication No. 2000-295084).

However, the above conventional technique has the following problem. Specifically, although the replica circuit is described as having delay characteristics equivalent to those of the critical path, the replica circuit provided at a position different from that of the critical path does not necessarily have the same delay, and therefore, it is necessary to adjust the amount of the delay using another delay element, leading to a complicated design process.

It is also necessary to provide a separate space for providing the replica circuit, the delay element, etc. When there are a plurality of critical paths, a space is required for each of the replica circuits, leading to an increase in the area of the semiconductor device, and therefore, an increase in manufacturing cost.

If a read path of a memory macro, such as a static random access memory (SRAM) device etc., is a critical path, it is difficult to produce a replica circuit having a delay equivalent to a read delay of a memory cell. Therefore, the monitoring circuit employing the replica circuit lacks versatility.

### SUMMARY

The present disclosure describes implementations of a versatile monitoring circuit which accurately monitors a delay value and is arranged without an increase in the area of a semiconductor device.

An example semiconductor device includes a monitoring circuit including a delay circuit including a plurality of elements and a plurality of interconnects arranged in a tree shape, a data supply circuit configured to supply a determination signal to the delay circuit, and a delay evaluation circuit connected to an end point of the delay circuit and configured to evaluate a delay state of the determination signal. The monitoring circuit controls at least one of a power supply voltage, a substrate voltage, and a clock frequency of a semiconductor circuit included in the semiconductor device.

According to the present disclosure, the power supply voltage can be decreased, the substrate voltage can be increased, or the clock frequency can be decreased within a range in which the circuit does not operate erroneously, based on a value determined by the monitoring circuit, whereby the power consumption of the semiconductor device can be reduced.

If a plurality of trees having different sizes, numbers of stages, constituent cells, or arrangements are provided, the monitoring circuit can be provided, taking into consideration a circuit having a high interconnect delay dependency, a circuit having a cell delay dependency, and a circuit having a local dependency in a chip. Therefore, more accurate delay monitoring can be achieved. The power supply voltage or the substrate voltage can be controlled based on the result of the monitoring, whereby the power consumption of the semiconductor device can be reduced.

Similarly, the clock frequency can be controlled based on the result of the monitoring, whereby the processing capability of the semiconductor device can be improved, and the power consumption of the semiconductor device can be reduced.

If the monitoring circuit is arranged in a space in an existing circuit, a space for the monitoring circuit is not required, whereby an increase in the area of the semiconductor device can be reduced.

The tree can be generated using a standard arrangement/interconnection layout tool, whereby a monitoring circuit with ease of development and versatility can be provided.

### BRIEF DESCRIPTION OF THE DRAWINGS

FIG. 1 is a block diagram showing a monitoring circuit in a semiconductor device according to the present disclosure.

FIG. 2 is a circuit diagram showing a specific example of the monitoring circuit of FIG. 1.

FIG. 3 is a diagram showing a layout of the monitoring circuit of FIG. 2.

FIG. 4 is a timing chart showing an example in which an output OUT of FIG. 2 goes high.

FIG. 5 is a timing chart showing an example in which the output OUT of FIG. 2 is maintained low.

FIG. 6 is a circuit diagram showing an example semiconductor device in which a power supply voltage or a substrate voltage is controlled, depending on the output OUT of FIG. 2.

FIG. 7 is a timing chart showing operation of the semiconductor device of FIG. 6.

FIG. 8 is a circuit diagram showing another example configuration of a buffer tree of FIG. 2.

FIG. 9 is a circuit diagram showing still another example configuration of the buffer tree of FIG. 2.

FIG. 10 is a circuit diagram showing a variation of the monitoring circuit of FIG. 2.

FIG. 11 is a diagram showing a layout of the monitoring circuit of FIG. 10.

FIG. 12 is a circuit diagram showing another specific example of the monitoring circuit of FIG. 1.

FIG. 13 is a circuit diagram showing an example semiconductor device in which a clock frequency is controlled, depending on the output OUT of FIG. 2.

FIG. 14 is a timing chart showing an example in which an output OUT of FIG. 13 is maintained low.

FIG. 15 is a timing chart showing an example in which the output OUT of FIG. 13 goes high.

### DETAILED DESCRIPTION

Embodiments of the present disclosure will be described hereinafter with reference to the accompanying drawings.

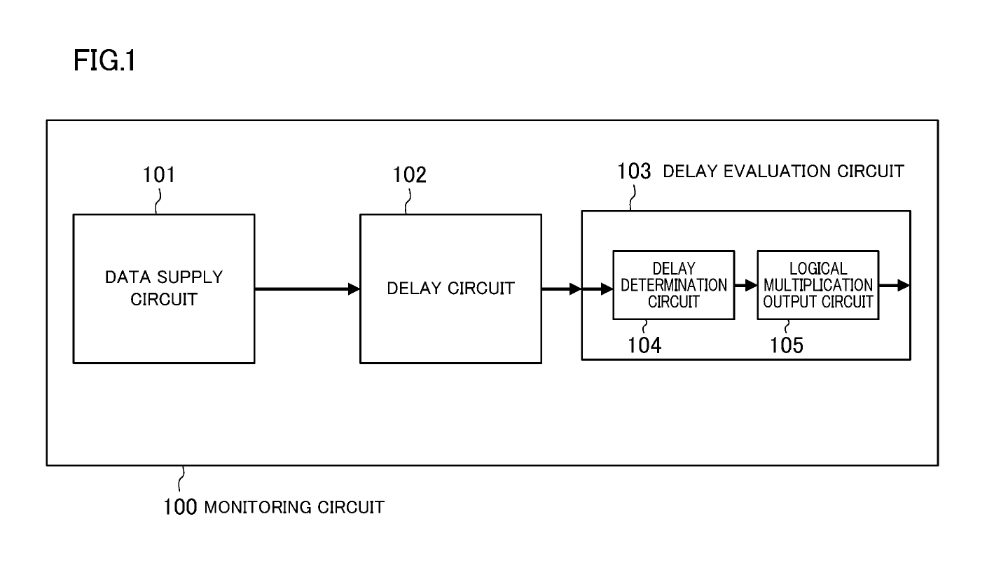

FIG. 1 is a block diagram showing a monitoring circuit 100 according to an embodiment. In FIG. 1, the monitoring circuit 100 includes a data supply circuit 101, a delay circuit 102, and a delay evaluation circuit 103. The delay evaluation circuit 103 includes a delay determination circuit 104 and a logical multiplication output circuit 105. These circuits are connected together in a sequence indicated by arrows in FIG. 1.

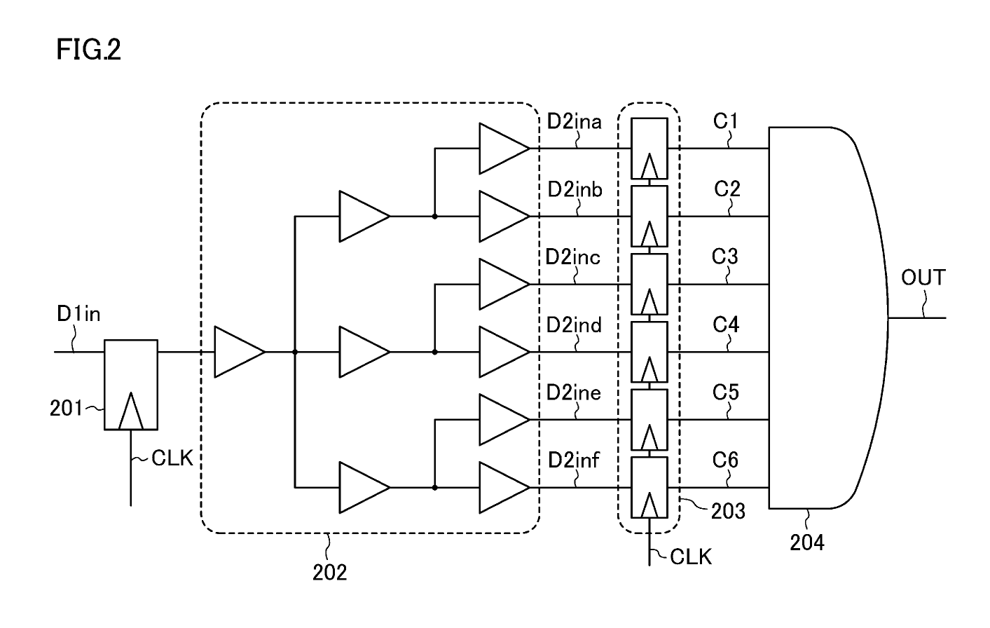

FIG. 2 shows a specific logic circuit form of each circuit of FIG. 1. The data supply circuit 101 is a flip-flop 201. The delay circuit 102 is a buffer tree 202. The delay evaluation circuit 103 includes flip-flops 203 included in the delay determination circuit 104, and an AND element 204 which is the logical multiplication output circuit 105. The circuits are connected together via interconnects. The monitoring circuit 100 is arranged in a space in an existing circuit in a semiconductor device so that a delay time between when a clock CLK is input to the flip-flop 201 and when a data signal reaches all the flip-flops 203 is substantially equal to a clock cycle.

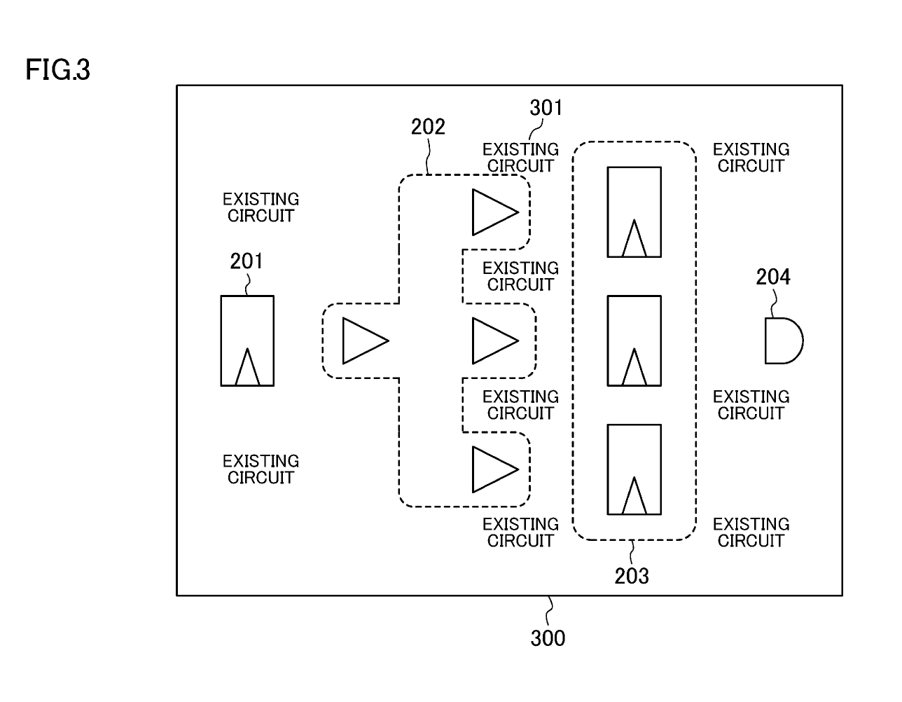

FIG. 3 shows an example layout of FIG. 2. In a semiconductor device 300, the circuits 201-204 included the monitoring circuit are arranged in a space in an existing circuit 301. An arrangement of the circuits 201-204 in which the delay time is substantially equal to a clock cycle may be determined by a human calculating the loads of buffer elements and interconnects. Alternatively, if the clock tree circuit generation function of a standard semiconductor device layout tool is used to design the arrangement and interconnection, the delay between the flip-flop 201 and the flip-flops 203 can be easily caused to be equal to a clock cycle.

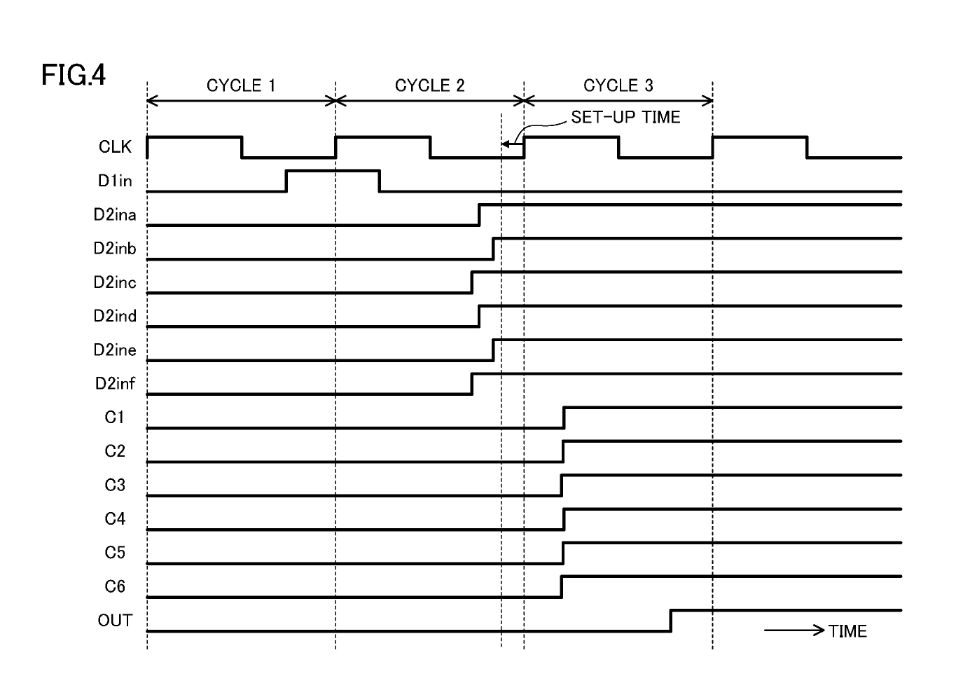

FIG. 4 is a timing chart of the circuit of FIG. 2. Clocks CLK having the same cycle time are input to the flip-flop 201 and the flip-flop 203. In cycle 1, D1 in goes high. In cycle 2, the flip-flop 201 outputs a high-level signal, which is propagated through the buffer tree 202 to reach the inputs D2ina-D2inf of the flip-flops 203 before set-up time. Because all the flip-flops 203 can store a high-level signal in cycle 2, the outputs C1-C6 of the flip-flops 203 are high in cycle 3, and therefore, the output OUT of the AND element 204 is also high.

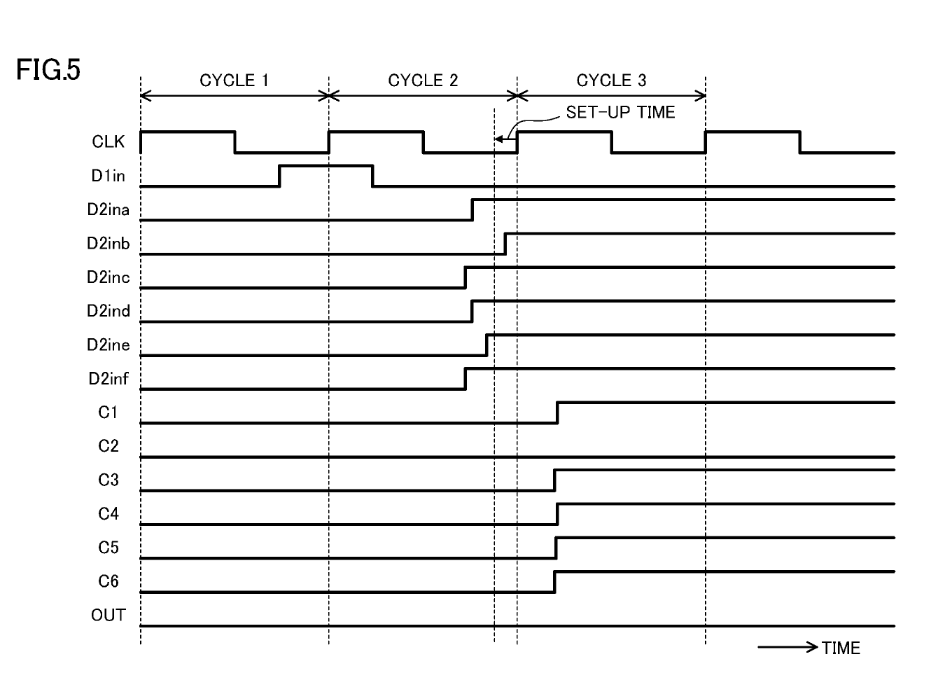

FIG. 5 is a timing chart showing an example in which a low-to-high transition at the terminal D2inb of one branch of the buffer tree 202 in cycle 2 has not been completed before the set-up time. In this case, the output OUT of the AND element 204 remains low.

As can be seen from the comparison between FIG. 4 and FIG. 5, when the output OUT of the AND element 204 goes high, the delay time between the flip-flop 201 and the flip-flops 203 is shorter than a clock cycle. Therefore, a power supply voltage supplied to a semiconductor circuit can be decreased, and a substrate voltage supplied to the semiconductor circuit can be increased.

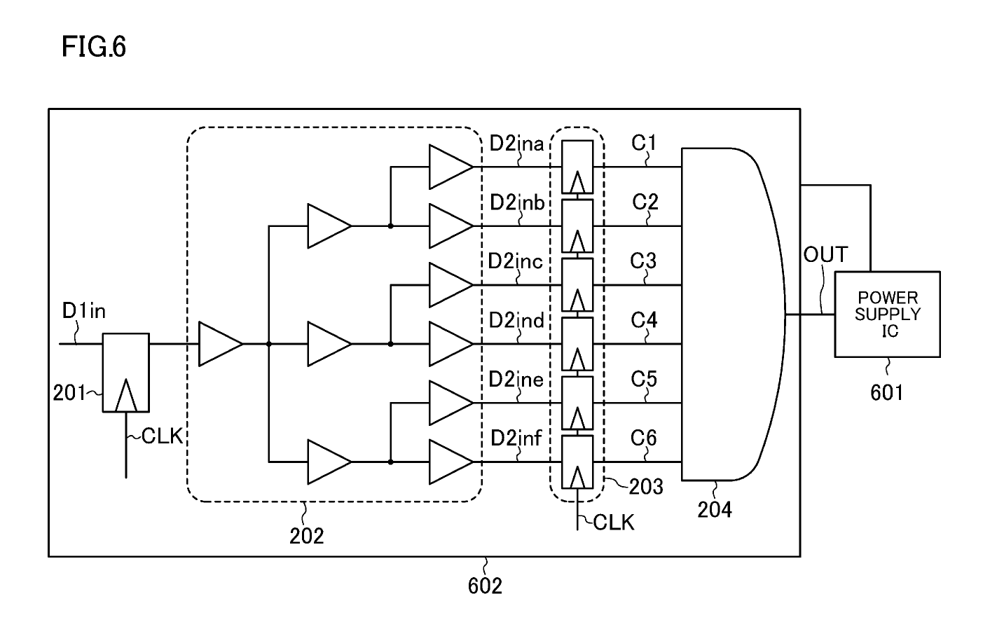

As shown in FIG. 6, for example, it is contemplated that the output OUT of the AND element 204 may be connected to a power supply integrated circuit (IC) 601, and the value of a power supply voltage supplied to a semiconductor device 602 may be decreased, or alternatively, the value of a substrate voltage supplied to the semiconductor device 602 may be increased.

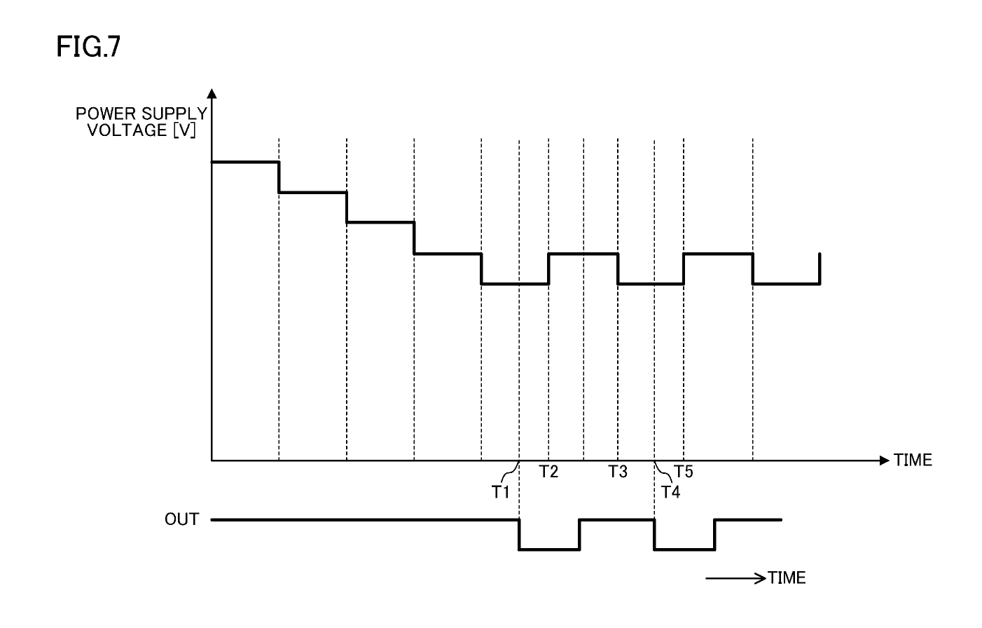

As shown in FIG. 7, if the power supply voltage is gradually decreased, so that the output OUT of the AND element 204 goes low at time T1, the power supply voltage is temporarily increased from time T2 to prevent the semiconductor device 602 from operating erroneously. At time T3, the power supply voltage is decreased again. If the output OUT of the AND element 204 goes low again at time T4, the power supply voltage is temporarily increased from time T5. By repeatedly performing this process, the power supply voltage is maintained at a low state, whereby power consumption is reduced. Here, the delay between the flip-flop 201 and the flip-flops 203 in FIG. 6 is designed to be longer than a delay in the critical path of the existing circuit. Therefore, when the power supply voltage supplied to the semiconductor device 602 decreases, the output OUT of the AND element 204 goes low before the critical path operates erroneously, whereby the power supply voltage is maintained at a predetermined value or more. Thus, by reducing the value of the power supply voltage to the extent possible, the power consumption of the semiconductor device 602 can be reduced. Note that when the substrate voltage supplied to the semiconductor device 602 is controlled, the value of the substrate voltage supplied from the power supply IC 601 is increased until the AND element 204 outputs a low-level signal, whereby power consumption can be reduced.

As shown in FIG. 3, the circuits 201-204 included in the monitoring circuit is arranged in a space in the existing circuit 301 of the semiconductor device 300, so that a space dedicated to the monitoring circuit is not required. Therefore, an increase in manufacturing cost due to an increase in the area of the semiconductor device 300 can be reduced or prevented.

In addition, a plurality of elements included in the delay circuit 102 are arranged using the clock tree circuit generation function of a semiconductor device layout tool so that delay times of determination signals received by the delay evaluation circuit 103 are caused to be substantially equal to one another. Therefore, a human does not have to design the arrangement of the monitoring circuit 100, resulting in easier design and a reduction in the number of design steps.

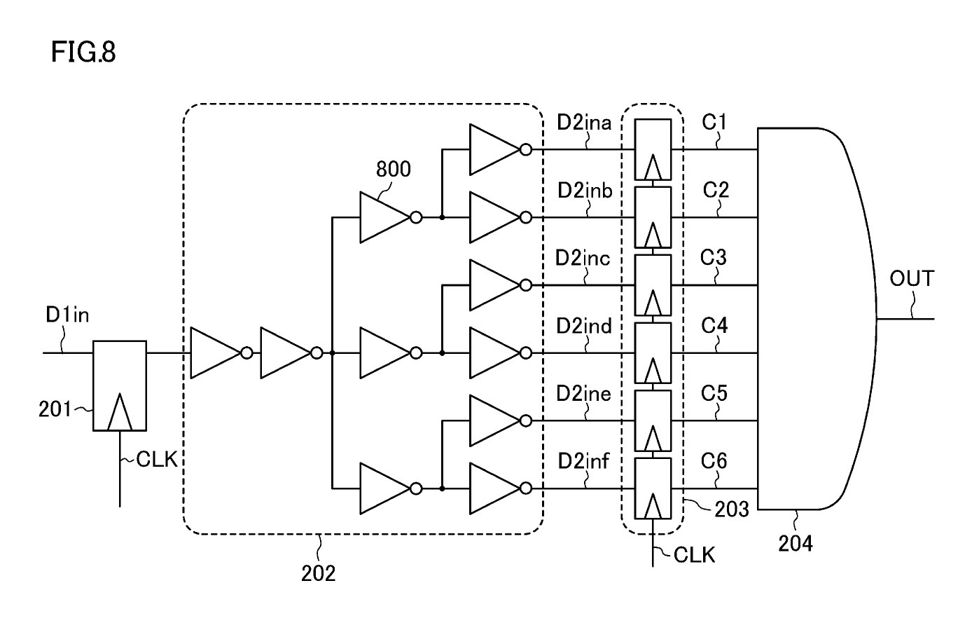

Although, in FIG. 2, the delay circuit 102 includes the buffer tree 202, as shown in FIG. 8 the tree may include inverter elements 800. The constituent element is not limited to an inverter element.

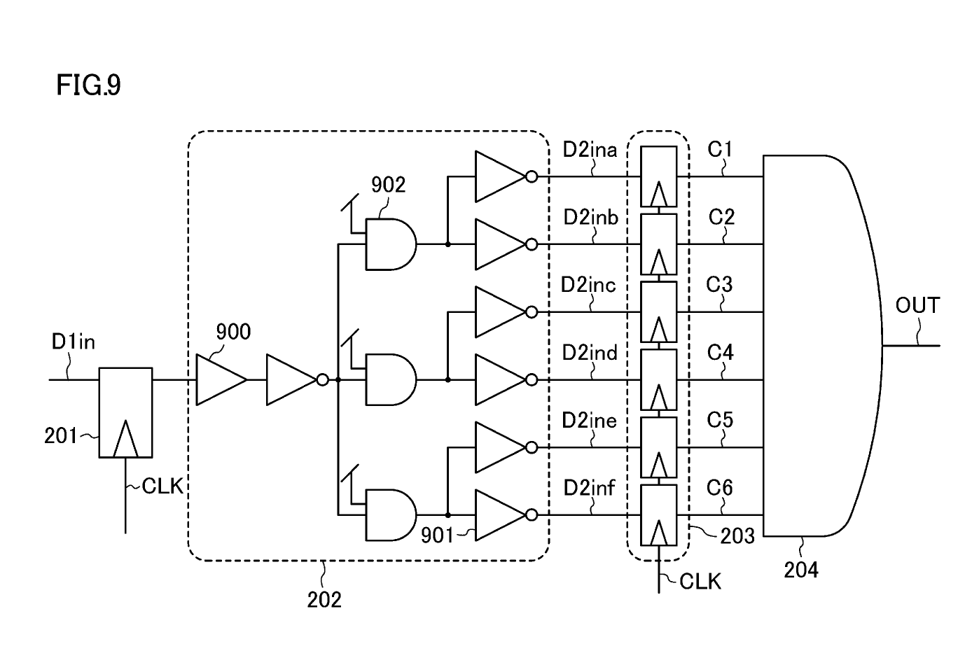

As shown in FIG. 9, the tree may include a buffer element 900, inverter elements 901, and AND elements 902. Thus, various elements may be used to form the tree, and therefore, a delay circuit can be adapted based on the delay dependency of a cell type, whereby highly accurate monitoring can be achieved.

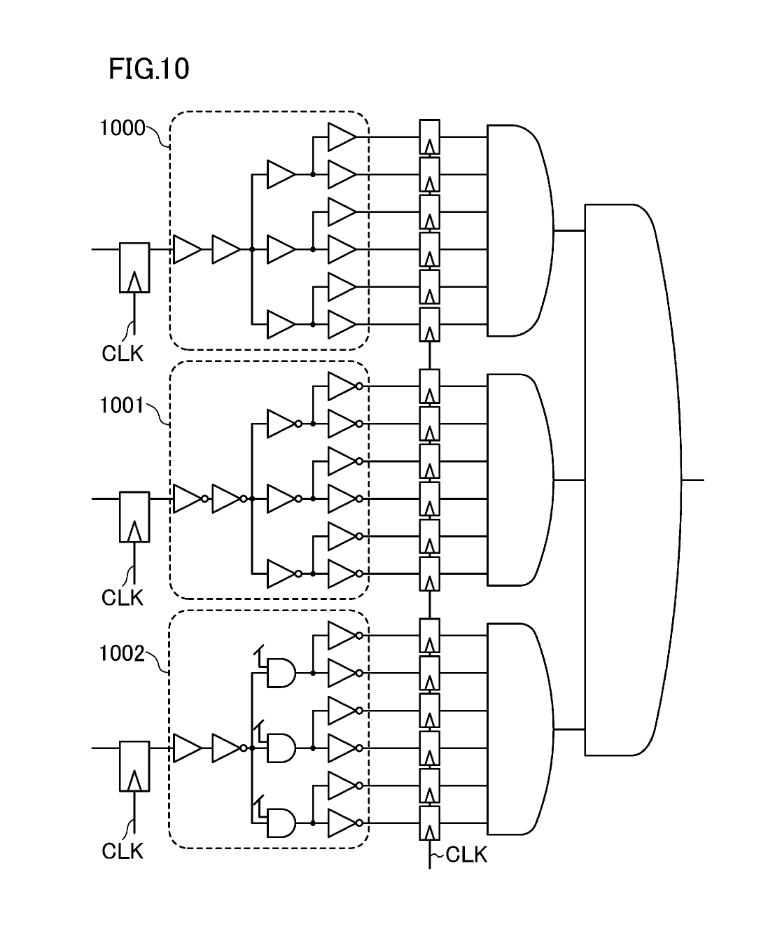

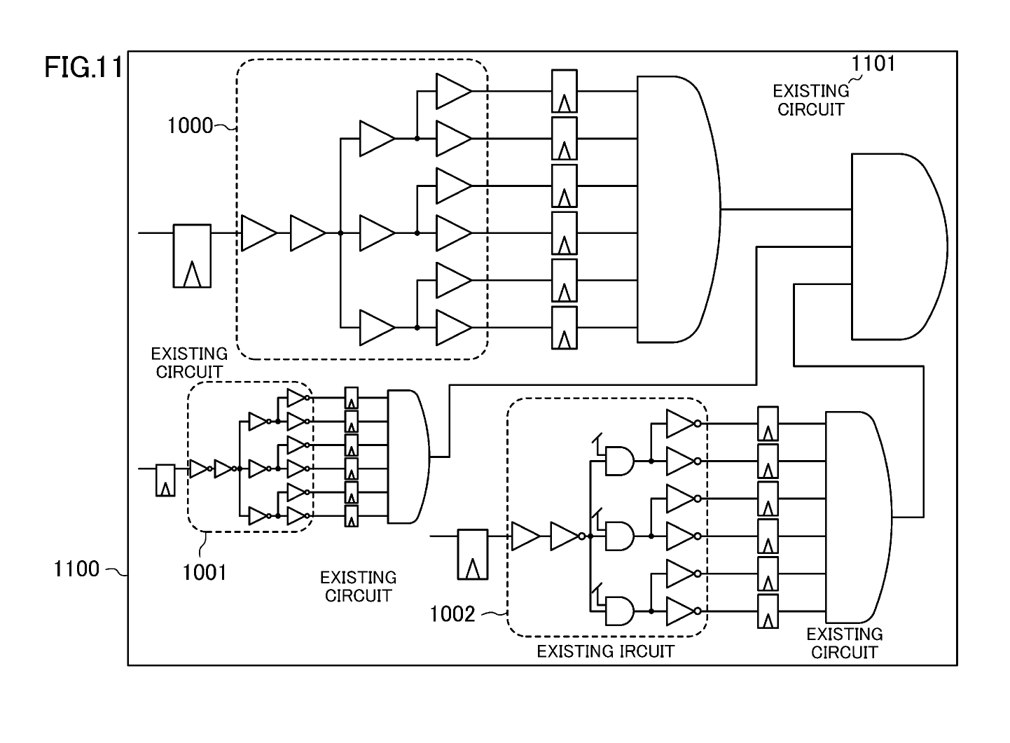

As shown in FIG. 10, a monitoring circuit may include a tree 1000 including only buffer elements, a tree 1001 including only inverter elements, and a tree 1002 including elements of a plurality of types. If the trees 1000, 1001, and 1002 are arranged in a space in an existing circuit 1101 of a semiconductor device 1100 by changing the size or location of the arrangement as shown in FIG. 11, a delay circuit having a high interconnect delay dependency, a delay circuit having a high cell delay dependency, or a delay circuit having a high local dependency in a chip, can be provided. Therefore, by calculating the logical multiplication of the delay evaluation results of these trees, more accurate monitoring can be achieved.

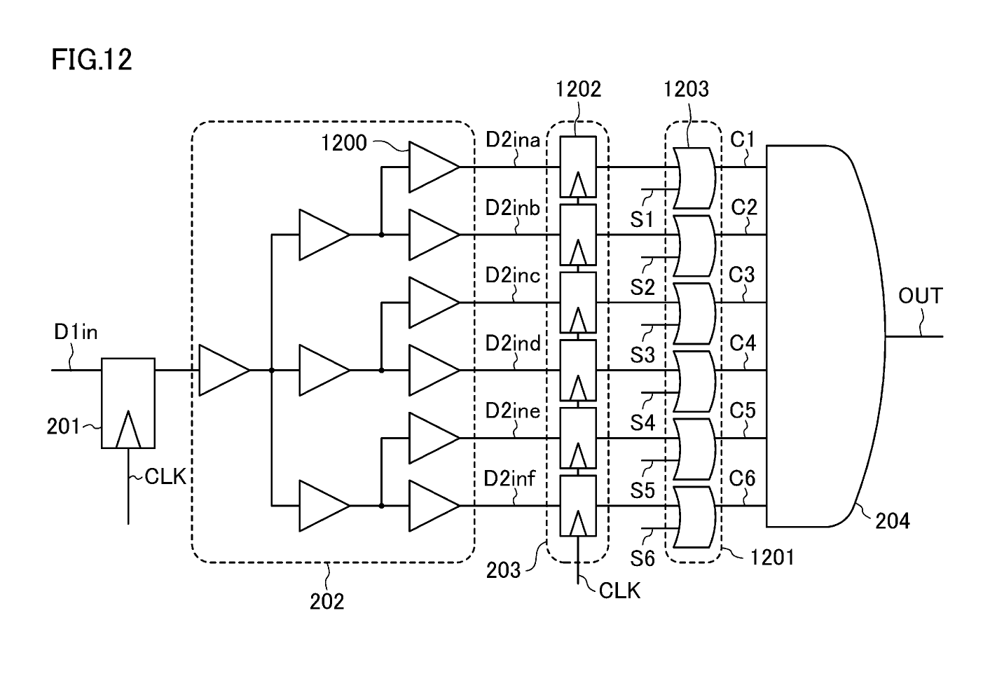

As shown in FIG. 12, a mask OR circuit 1201 may be connected to the outputs of the flip-flops 203. Active signals S1-S6 are each connected to one input of a corresponding one of a plurality of mask OR elements 1203 included in the mask OR circuit 1201, whereby a portion of the delay evaluation results can be fixed to the high level. For example, when a buffer element 1200 is provided in a region where a power supply is not provided, the input of the flip-flop element 1202 may become unstable. Therefore, by fixing the active signal S1 to the high level, the output of the mask OR element 1203 can be fixed to the high level. In this case, if the active signals S2-S6 are fixed to the low level, the output OUT of the AND element 204 can be determined based on the delay evaluation results of D2inb-D2inf. Thus, monitoring can be performed using only a portion of the results of the delay circuit.

Although, in FIG. 6, the power supply voltage or the substrate voltage supplied to the semiconductor device 602 is controlled, the clock frequency may be controlled.

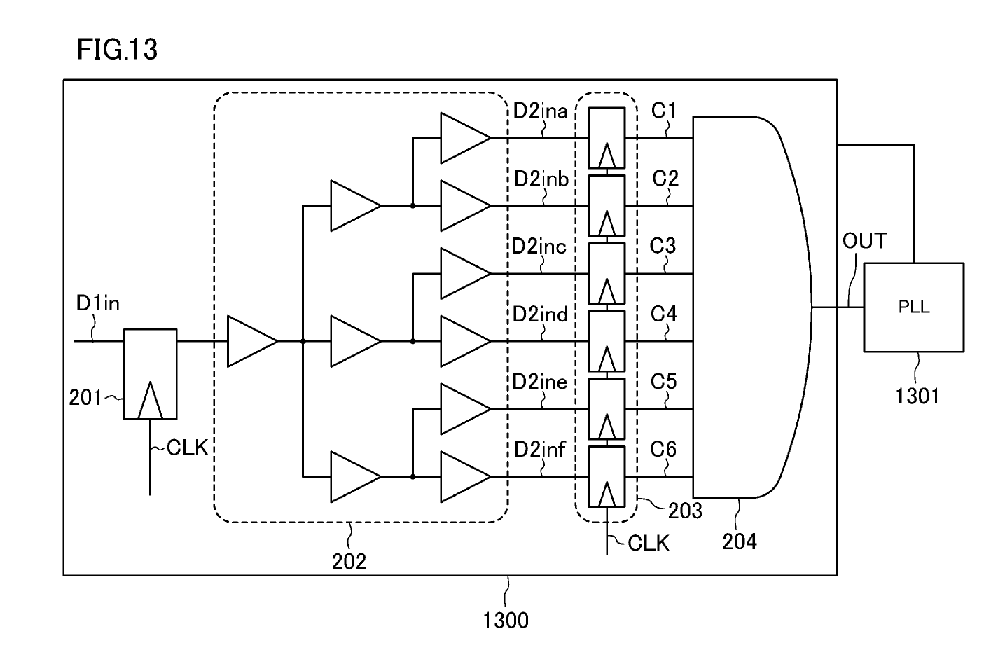

FIG. 13 is a diagram showing an example in which a phase-locked loop (PLL) 1301 which supplies a clock signal to a semiconductor device 1300 is controlled based on the output OUT of the AND element 204. The PLL 1301 decreases the clock frequency when the output OUT of the AND element 204 is low, and increases the clock frequency when the output OUT of the AND element 204 is high.

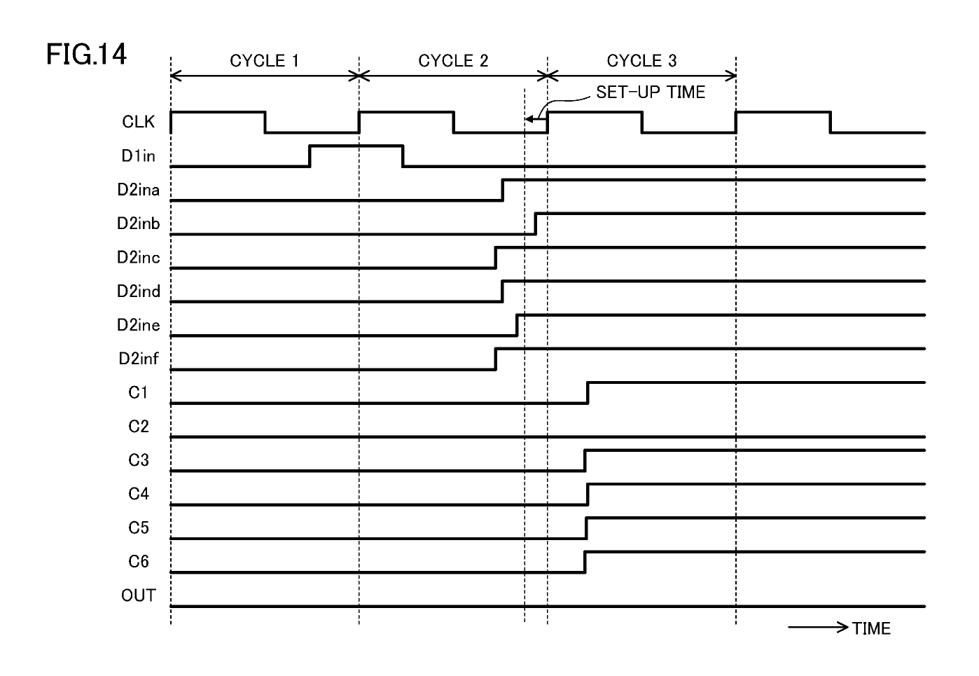

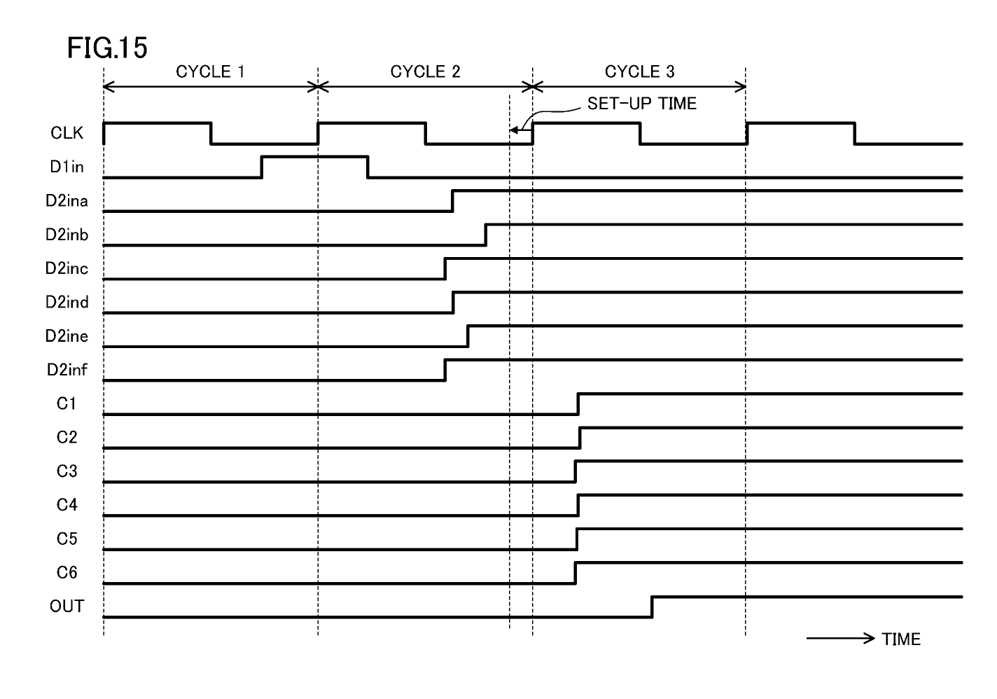

FIG. 14 is a timing chart showing an example in which the output OUT of the AND element 204 which is maintained low. FIG. 15 is a timing diagram showing an example in which the output OUT of the AND element 204 which goes high. The clock cycle is longer in FIG. 15 than in FIG. 14. Therefore, all transitions are completed before the set-up time in cycle 2 in FIG. 15. For example, when the semiconductor device 1300 operates at high temperature, then if the semiconductor device 1300 which normally operates at room temperature operates erroneously, the clock frequency is decreased so that the output OUT of the AND element 204 goes high, whereby allowing the semiconductor device 1300 to operate normally. Also, the reduction in the clock frequency leads to a reduction in power consumption.

In the semiconductor device of the present disclosure, the power supply voltage, the substrate voltage, and the clock frequency can be controlled by monitoring a delay time using a monitoring circuit. Therefore, the semiconductor device of the present disclosure is useful for reduction of power consumption.

What is claimed is:

1. A semiconductor device comprising:
a monitoring circuit including
a delay circuit including a plurality of elements and a plurality of interconnects arranged in a tree shape,
a data supply circuit configured to supply a determination signal to the delay circuit, and
a delay evaluation circuit connected to an end point of the delay circuit and configured to evaluate a delay state of the determination signal,
wherein
the monitoring circuit controls at least one of a power supply voltage, a substrate voltage, and a clock frequency of a semiconductor circuit included in the semiconductor device.

2. The semiconductor device of claim 1, wherein
the monitoring circuit controls a value of an output voltage of a power supply integrated circuit (IC) to increase and decrease a value of the power supply voltage supplied to the semiconductor circuit.

3. The semiconductor device of claim 1, wherein
the monitoring circuit controls a value of an output voltage of a power supply integrated circuit (IC) to increase and decrease a value of the substrate voltage supplied to the semiconductor circuit.

4. The semiconductor device of claim 1, wherein
the monitoring circuit controls a value of an output frequency of a phase-locked loop (PLL) to increase and decrease the clock frequency supplied to the semiconductor circuit.

5. The semiconductor device of claim 1, wherein
the delay circuit includes elements of a single type.

6. The semiconductor device of claim 1, wherein
the delay circuit includes elements of a plurality of types.

7. The semiconductor device of claim 1, wherein
elements of the monitoring circuit are disposed and distributed between circuits other than the monitoring circuit.

8. The semiconductor device of claim 1, wherein
the plurality of elements included in the delay circuit are arranged using a clock tree circuit generation function of a semiconductor device layout tool so that delay times of determination signals received by the delay evaluation circuit are caused to be substantially equal to one another.

9. The semiconductor device of claim 1, wherein
the delay evaluation circuit includes
a plurality of delay determination circuits configured to store output values at a plurality of end points of the delay circuit, and
a logical multiplication output circuit configured to output a logical multiplication of the values stored by the delay determination circuit.

10. The semiconductor device of claim 1, wherein
an output of the delay evaluation circuit is changed by inputting a control signal to the delay evaluation circuit.
